(19) United States
(12) Patent Application Publication
(10) Pub. No.: US 2024/0418544 A1
(43) Pub. Date: Dec. 19, 2024

(54) CAPACITIVE DOOR SENSOR AND ELECTRONIC DEVICE EMPLOYING SAME

(71) Applicant: Samsung Electronics Co., Ltd., Suwon-si (KR)

(72) Inventors: Boeun JANG, Suwon-si (KR); Daesung KANG, Suwon-si (KR); Sooam KIM, Suwon-si (KR); Sangho PARK, Suwon-si (KR); Buyeong KWAK, Suwon-si (KR); Seunggu JI, Suwon-si (KR)

(73) Assignee: Samsung Electronics Co., Ltd., Suwon-si (KR)

(21) Appl. No.: 18/819,393

(22) Filed: Aug. 29, 2024

Related U.S. Application Data
(63) Continuation of application No. PCT/KR2022/019681, filed on Dec. 6, 2022.

(30) Foreign Application Priority Data
May 9, 2022 (KR) 10-2022-0056880

(51) Int. Cl. G01D 5/24; E05B 65/00; E05F 15/611

(52) U.S. Cl. CPC G01D 5/24; E05B 65/00; E05F 15/611; E05Y 2400/852; E05Y 2900/30

(57) ABSTRACT

An electronic device including a main body having an opening, a door configured to open and close at least a part of the opening of the main body, and a door sensor, provided relative to an open-side edge of the door, to detect a touch input by using a capacitive method. The door sensor includes a touch key configured to receive the touch input, a sensor substrate comprising a conductive land; a connection member including a sensing surface contacting the touch key, and a connection surface contacting the conductive land so that the touch key is electrically connected with the conductive land through the connection member. Surfaces of the connection member along a thickness direction including the sensing surface and the connection surface and surfaces of the connection member along a longitudinal direction are electrically conductive surfaces. Surfaces of the connection member along a width direction are electrically non-conductive surfaces.

### CROSS-REFERENCE TO RELATED APPLICATION

This application is a continuation application, under 35 U.S.C. § 111(a), of international application No. PCT/KR2022/019681, filed Dec. 6, 2022, which claims priority under 35 U. S. C. § 119 to Korean Patent Application No. 10-2022-0056880, filed on May 9, 2022, the disclosures of which are incorporated herein by reference in their entireties.

### TECHNICAL FIELD

Embodiments of the disclosure relate to a capacitive door sensor that detects a touch signal for opening a door and an electronic device employing the capacitive door sensor.

### BACKGROUND ART

An electronic device, such as a refrigerator, a washing machine, or an oven, includes a door that partially or fully opens/closes a main body. The door may be manually opened/closed or may be automatically opened/closed partially or fully. A door sensor may be provided on the door. The door sensor may be a capacitive sensor. The capacitive door sensor includes a touch key. When a user's hand touches the touch key, capacitance changes. The sensor detects whether there is a touch based on a change in capacitance. An electronic device may unlock the door or may switch the door to a partially or fully open state based on a touch detection signal of the door sensor.

### DISCLOSURE

### Technical Solution

An electronic device according to an aspect of the disclosure includes a main body having an opening and a door configured to open and close at least a part of the opening of the main body. A door sensor is provided on the door. The door sensor may be provided relative to an open-side edge of the door and configured to detect a touch input by using a capacitive method. The door sensor may include a touch key configured to receive the touch input. A connection member may include a sensing surface contacting the touch key, and a connection surface. A sensor substrate includes a conductive land contacting the connection surface. Surfaces of the connection member along a thickness direction including the sensing surface and the connection surface and surfaces of the connection member along a longitudinal direction parallel to the open-side edge of the door are electrically conductive surfaces. Surfaces of the connection member along a width direction, which is an opening/closing direction of the door, are electrically non-conductive surfaces.

A door sensor according to an aspect of the disclosure includes a touch key, a sensor substrate, and a connection member between the touch key and the sensor substrate. The touch key is configured to receive a touch input. The connection member may include a sensing surface contacting the touch key and a connection surface. A sensor substrate may include a conductive land contacting the connection surface. Surfaces of the connection member along a thickness direction including the sensing surface and the connection surface and surfaces of the connection member along a longitudinal direction parallel to the open-side edge of the door are electrically conductive surfaces. Surfaces of the connection member along a width direction are electrically non-conductive surfaces.

### DESCRIPTION OF DRAWINGS

FIG. 1 is a schematic perspective view illustrating an electronic device, according to an embodiment of the disclosure.

FIG. 2 is a cross-sectional view taken along line Y1-Y1′ of FIG. 1, according to an embodiment of the disclosure.

FIG. 3 is a schematic perspective view illustrating an example of a connection member, according to an embodiment of the disclosure.

FIG. 4 is a front view illustrating an example of an arrangement of two electronic devices, according to an embodiment of the disclosure.

FIG. 5 is a front view illustrating an example of an arrangement of two electronic devices, according to an embodiment of the disclosure.

FIG. 6 is an exploded perspective view illustrating an example of a connection member, according to an embodiment of the disclosure.

FIG. 7 is a schematic perspective view illustrating an example of a connection member, according to an embodiment of the disclosure.

FIG. 8 is a schematic perspective view illustrating an example of a connection member, according to an embodiment of the disclosure.

FIG. 9 is a schematic perspective view illustrating an example of a connection member, according to an embodiment of the disclosure.

FIG. 10 is a schematic perspective view illustrating an example of an arrangement of two electronic devices, according to an embodiment of the disclosure.

FIG. 11 is a schematic perspective view illustrating an example of an arrangement of two electronic devices, according to an embodiment of the disclosure.

### MODE FOR INVENTION

The terms used herein are general terms currently widely used in the art in consideration of functions in the disclosure, but the terms may vary according to the intention of one of ordinary skill in the art, precedents, or new technology in the art. Also, some of the terms used herein may be arbitrarily chosen by the present applicant, and in this case, these terms are defined in detail below. Accordingly, the specific terms used herein should be defined based on the unique meanings thereof and the whole context of the disclosure. It will be understood that when a certain part “includes” a certain component, the part does not exclude another component but may further include another component, unless the context clearly dictates otherwise.

Embodiments will now be described more fully with reference to the accompanying drawings for one of ordinary skill in the art to be able to perform the embodiments without any difficulty. However, the disclosure may be embodied in many different forms and is not limited to the embodiments set forth herein. For clarity, portions irrelevant to the descriptions of the disclosure are omitted in the drawings, and like components are denoted by like reference numerals throughout the specification. Hereinafter, embodiments of the disclosure will be described with reference to the accompanying drawings.

A conductor around a capacitive door sensor may affect the capacitive door sensor. When two electronic devices (e.g., refrigerators) are located adjacent to each other, an opening/closing operation of a door of one refrigerator may affect a door sensor of the other refrigerator. The disclosure provides a capacitive door sensor capable of reducing the influence of a surrounding conductor and an electronic device employing the capacitive door sensor. The disclosure provides a capacitive door sensor with improved operational stability and an electronic device employing the same.

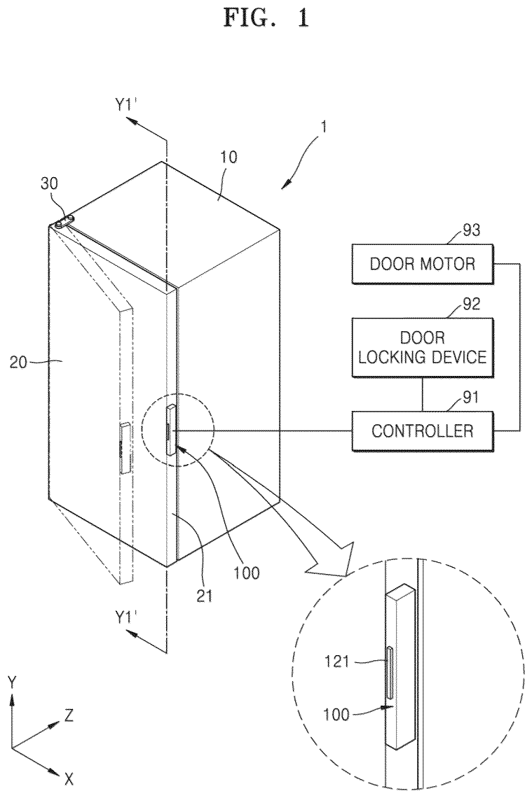

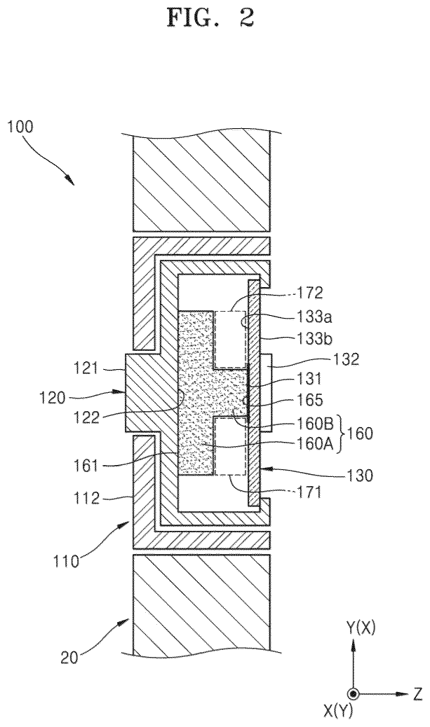

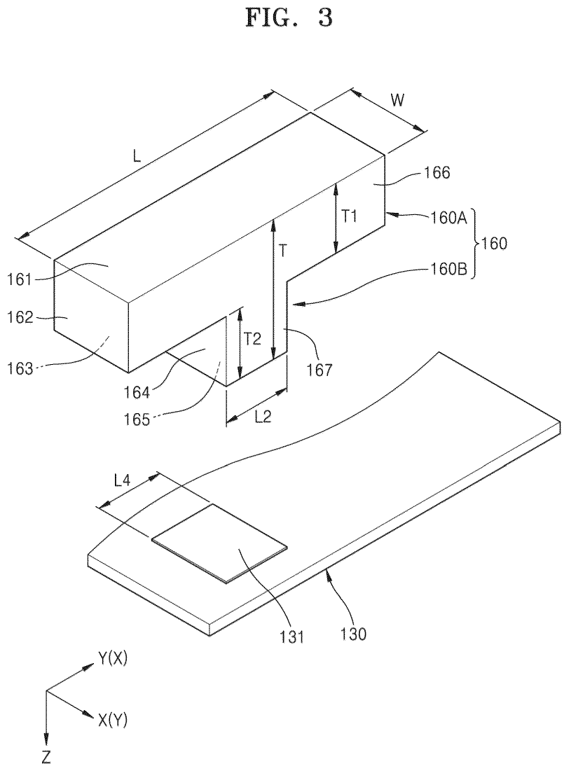

FIG. 1 is a schematic perspective view illustrating an electronic device 1, according to an embodiment of the disclosure. FIG. 2 is a cross-sectional view taken along line Y1-Y1′ of FIG. 1. FIG. 3 is a schematic perspective view illustrating an example of a connection member 150. Referring to FIGS. 1 to 3, an example of the electronic device 1 may include a main body 10, a door 20 configured to open/close at least a part of the main body 10, and a door sensor 100 provided on the door 20 and configured to detect a door opening signal (touch input).

For example, the electronic device 1 may be a refrigerator. The main body 10 may include a refrigerating compartment and/or a freezing compartment, and a cooling system configured to supply cooled air to the refrigerating compartment and the freezing compartment. The door 20 is configured to open/close the refrigerating compartment and/or the freezing compartment. For example, the electronic device 1 may be a washing machine. The main body 10 may include a washing tub, a washing water supply system configured to supply washing water to the washing tub, a detergent supply system configured to supply detergent to the washing tub, and a washing tub driving system configured to drive the washing tub. The door 20 may be configured to open/close the washing tub. For example, the electronic device 1 may include an oven. The main body 10 may include a cooking chamber and various heating systems configured to heat an object to be cooked inside the cooking chamber. For example, the heating systems may include a microwave heating system, a light wave heating system, and a gas heating system. The door 20 may be configured to open/close the cooking chamber. In the present example, the electronic device 1 may be a refrigerator.

The door 20 may be configured to open/close at least a part of the main body 10 by using various methods such as rotation and sliding. In the present example, the door 20 may rotate around a hinge 30 as an axis as marked by a dotted line in FIG. 1 to open/close at least a part of the main body 10.

When a user's touch input is detected through the door sensor 100, the electronic device 1 may unlock the door 20. The door sensor 100 of the present example detects a touch input by using a capacitive method. The door sensor 100 measures a change amount in capacitance due to a touch signal input through a touch key 120 described below. For example, the term “change amount in capacitance” may refer to an absolute value of a difference between a real-time sensing value and a reference value. The term “reference value” may refer to an average of initial sensing values. The change amount in capacitance measured by the door sensor 100 is input to a controller 91. The controller 91 may include, for example, a central processing unit (CPU). Although not shown, the controller 91 may include a memory. An application program for controlling the electronic device 1 may be stored in the memory. The controller 91 may recognize that a touch input is detected when the change amount in capacitance input from the door sensor 100 is greater than a preset threshold value and may recognize that a touch input is not detected when the change amount in capacitance is less than the preset threshold value. When a touch input is detected, the controller 91 may unlock the door 20 by driving a door locking device 92. The user may switch, for example, rotate, the door 20 to an open position by pulling the door 20. The controller 91 may drive a door motor 93 to switch, for example, rotate, the door 20 to an open position. The controller 91 may drive the door motor 93 to slightly switch the door 20 toward an open position, for example, to a rotated partial open position, as marked by a dotted line in FIG. 1.

The door sensor 100 may be provided on the door 20. For example, the door sensor 100 may be provided adjacent to the open-side edge 21 of the door 20. The open-side edge 21 may be, for example, an edge opposite to the hinge 30. An example of the door sensor 100 may include the touch key 120 configured to receive a touch input, a sensor substrate 130 including a conductive land 131 and configured to detect whether there is a touch input, and a connection member 160 configured to electrically connect the touch key 120 to the conductive land 131.

The touch key 120 is accommodated in a sensor housing 110. The sensor housing 110 may accommodate therein the touch key 120, the sensor substrate 130, and the connection member 160. The touch key 120 may include a touch unit 121 configured to receive an input of a touch signal. The touch unit 121 may be located on a front surface of the door 20, for example, toward a −Z direction in FIG. 1. The touch unit 121 is exposed from the sensor housing 110. The touch unit 121 is exposed from a top surface 112 of the sensor housing 110. The touch unit 121 may be at the same height as the top surface 112 of the sensor housing 110 or may slightly protrude from the top surface 112 of the sensor housing 110. For example, the user may provide a touch input for opening the door 20 by touching a body part, for example, a finger, to an exposed portion of the touch unit 121.

The sensor substrate 130 may include the conductive land 131 electrically connected to the touch key 120. The conductive land 131 may be provided on a surface 133a facing the touch key 120 from among two surfaces 133a and 133b of the sensor substrate 130. The sensor substrate 130 may include a sensor circuit unit 132 connected to the conductive land 131 and configured to detect whether a touch signal is input by using a capacitive method. For example, the sensor circuit unit 132 may be provided on the surface 133b of the sensor substrate 130. The conductive land 131 and the sensor circuit unit 132 may be electrically connected to each other by an electrically conductive pattern (not shown).

The connection member 160 electrically connects the touch key 120 to the conductive land 131. For example, the connection member 160 contacts the touch key 120 and the conductive land 131. The connection member 160 has a length L, a width W, and a thickness T. The length L is a value measured in a direction Y parallel to the open-side edge 21 of the door 20. The width W is a value measured in an opening/closing direction X of the door 20. Hereinafter, directions in which the length L, the width W, and the thickness T are measured are respectively referred to as a longitudinal direction, a width direction, and a thickness direction, and are respectively denoted by Y, X, and Z.

For example, the connection member 160 may be located between the touch key 120 and the sensor substrate 130 in the thickness direction Z. The connection member 160 includes surfaces 161, 163, and 165 in the thickness direction Z, surfaces 162 and 164 in the longitudinal direction Y, and surfaces 166 and 167 in the width direction X. One surface (sensing surface) 161 of the connection member 160 in the thickness direction Z contacts the touch key 120, for example, a bottom surface 122 of the touch unit 121. The bottom surface 122 is a surface opposite to the touch unit 121 in the thickness direction Z. Another surface (connection surface) 165 of the connection member 160 in the thickness direction Z contacts the conductive land 131. The surfaces 161, 163, and 165 of the connection member 160 in the thickness direction Z and the surfaces 162 and 164 in the longitudinal direction Y are electrically conductive surfaces, and the surfaces 166 and 167 of the connection member 160 in the width direction X are electrically non-conductive surfaces. The surface (sensing surface) 161 and the surface (connection surface) 165 of the connection member 160 are electrically connected to each other through the surfaces 162, 163, and 164 in the thickness direction Z and the longitudinal direction Y which are electrically conductive surfaces. Accordingly, a touch signal input through the touch key 120 may be transmitted to the conductive land 131 through the connection member 160.

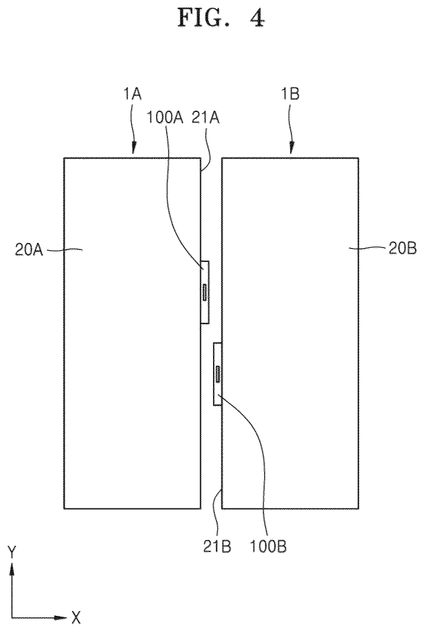

FIG. 4 is a front view illustrating an example of an arrangement of two electronic devices 1A and 1B. Referring to FIG. 4, the two electronic devices 1A and 1B are arranged parallel to each other in the width direction X. The two electronic devices 1A and 1B are arranged so that open-side edges 21A and 21B of doors 20A and 20B are adjacent to each other. Each of the doors 20A and 20B entirely or partially includes a conductor, for example, a metal. For example, when the door 20B of the electronic device 1B is opened/closed in a state where the door 20A of the electronic device 1A is closed, the door 20B is spaced apart from a door sensor 100A of the electronic device 1A and approaches the door sensor 100A again. Opening/closing of the door 20B has the same effect as a conductor being spaced apart from and then approaching the door sensor 100A of the electronic device 1A. When the door 20B is opened/closed, due to parasitic capacitance caused by the conductor of the door 20B of the electronic device 1B, a change amount in capacitance may be detected in the door sensor 100A of the electronic device 1A. When the door 20A of the electronic device 1A is opened/closed, parasitic capacitance of the door 20A may also affect a door sensor 1001B of the electronic device 1B. The influence of parasitic capacitance increases as a separation distance between the two electronic devices 1A and 1B decreases. When a change amount in capacitance of the door sensors 100A and 1001B due to parasitic capacitance is greater than a threshold value, the controller 91 may recognize that a touch input is detected and may unlock the doors 20A and 20B.

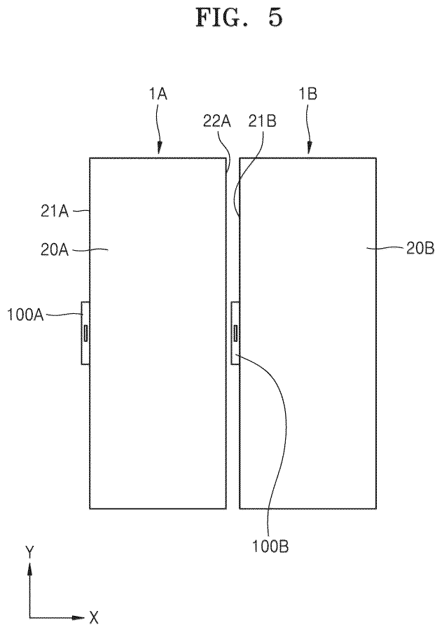

FIG. 5 is a front view illustrating an example of an arrangement of the two electronic devices 1A and 1B. Referring to FIG. 5, the two electronic devices 1A and 1B are arranged parallel to each other in the width direction X. The two electronic devices 1A and 1B are arranged so that an hinge-side edge 22A of the door 20A of the electronic device 1A and an open-side edge 21B of the door 20B of the electronic device 1B are adjacent to each other. For example, when the door 20A of the electronic device 1A is opened/closed in a state where the door 20B of the electronic device 1B is closed, the door 20A approaches and then is spaced apart from the door sensor 100B of the electronic device 1B. A change amount in capacitance may be detected in the door sensor 100B of the electronic device 1B due to parasitic capacitance caused by the conductor of the door 20A. When the change amount in capacitance of the door sensor 100B due to parasitic capacitance is greater than a threshold value, the controller 91 may recognize that a touch input is detected and may unlock the door 20B.

As such, when the electronic devices 1A and 1B are located adjacent to each other, the door sensors 100A and 100B may malfunction due to parasitic capacitance. The influence of parasitic capacitance increases as a distance between the electronic device 1A and the electronic device 1B decreases. According to a non-limiting example, when the electronic devices 1A and 1B are spaced apart from each other by about 15 mm, a change amount in capacitance is almost close to a threshold value.

For example, in FIG. 4, when the door 20B of the electronic device 1B is opened/closed, the door 20B of the electronic device 1B approaches/is spaced apart from the connection member 160 of the door sensor 100A of the electronic device 1A in the width direction X. When the connection member 160 is entirely an electrical conductor, parasitic capacitance caused by opening/closing the door 20B of the electronic device 1B has a significant influence on the connection member 160. According to the door sensor 100 of the present example, the surfaces 166 and 167 of the connection member 160 in the width direction X are electrically non-conductive surfaces. According to this configuration, the influence of parasitic capacitance caused by a conductor approaching/spaced apart from the door sensor 100 in the width direction X may be reduced, thereby reducing the risk of malfunction of the door sensor 100. Also, the capacitive door sensor 100 with improved operational stability and the electronic device 1 employing the same may be implemented.

To further reduce the influence of parasitic capacitance caused by a conductor approaching/spaced apart from the door sensor 100 in the width direction X, the areas of the surfaces 166 and 167 of the connection member 160 in the width direction X may be reduced. Referring to FIGS. 2 and 3, the connection member 160 includes a first portion 160A and a second portion 160B. For example, each of the first portion 160A and the second portion 160B may have a rectangular parallelepiped shape. A length L2 of the second portion 160B is less than the length L of the first portion 160A. A thickness T1 of the first portion 160A and a thickness T2 of the second portion 160B may be the same or different from each other. The first portion 160A and the second portion 160B may have the same width W. The connection member 160 has a substantially T-shape. According to this configuration, the area of the surface (sensing surface) 161 contacting the touch key 120 may be sufficiently secured, and the areas of the surfaces 166 and 167 of the connection member 160 in the width direction X may be reduced.

A length L4 of the conductive land 131 may be less than the length L of the connection member 160, for example, the first portion 160A. The length L4 of the conductive land 131 may be the same as or slightly less or greater than the length L2 of the second portion 160B. According to this configuration, the influence of parasitic capacitance caused by a conductor approaching/spaced apart from the door sensor 100 in the width direction X directly on the conductive land 131 may be reduced.

Referring back to FIG. 2, the door sensor 100 may further include support members 171 and 172. The support members 171 and 172 are located between the sensor substrate 130 and the first portion 160A to support the first portion 160A. To reduce the influence of parasitic capacitance, each of the support members 171 and 172 may be formed of an electrically insulating material. The support members 171 and 172 may be formed of, for example, polyurethane sponge. For example, the support members 171 and 172 may be adhered to the first portion 160A, for example, the surface 163, by using a double-sided tape or an adhesive. The double-sided tape and the adhesive may be electrically insulating. According to this configuration, the surface (sensing surface) 161 of the first portion 160A may stably contact the bottom surface 122 of the touch key 120.

The connection member 160 may be an elastic member. The connection member 160 may be elastically contracted and located between the sensor substrate 130 and the touch key 120, for example, the bottom surface 122 of the touch key 120. Accordingly, the surface (sensing surface) 161 and the surface (connection surface) 165 of the connection member 160 may stably contact the bottom surface 122 of the touch key 120 and the conductive land 131, respectively. The support members 171 and 172 may also be elastic members.

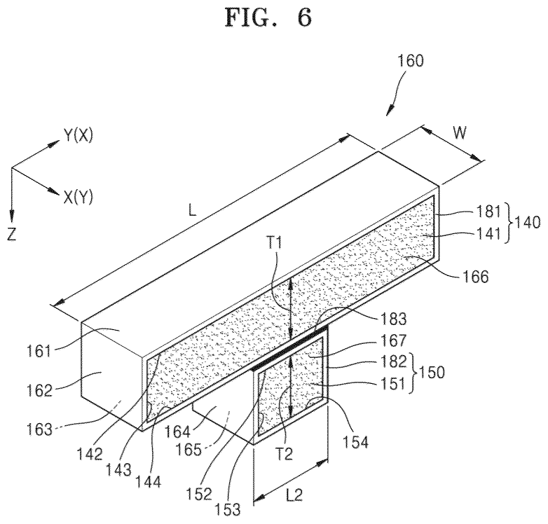

FIG. 6 is an exploded perspective view illustrating an example of the connection member 160. Referring to FIG. 6, the connection member 160 may include a first member 140 and a second member 150. The first member 140 and the second member 150 respectively correspond to the first portion 160A and the second portion 160B of FIGS. 2 and 3. The first member 140 may have the length L, the width W, and the thickness T1. The first member 140 may include a first gasket 141 that is electrically insulating, and a first sheet 181 that is electrically conductive and surrounds surfaces 142, 143, and 144 of the first gasket 141 in the longitudinal direction Y and the thickness direction Z. The first gasket 141 may be formed of an electrically insulating material having elasticity. For example, the first gasket 141 may be formed of polyurethane sponge. The first sheet 181 covers the surfaces 142, 143, and 144 of the first gasket 141 in the longitudinal direction Y and the thickness direction Z. The first sheet 181 may surround the surfaces 142, 143, and 144 of the first gasket 141 in the longitudinal direction Y and the thickness direction Z. The first sheet 181 may be adhered to the surfaces 142, 143, and 144 of the first gasket 141 in the thickness direction Z and the longitudinal direction Y. The first sheet 181 may include an electrically conductive fabric. The first sheet 181 may be, for example, a polyester fabric including nickel (Ni) or copper (Cu). Accordingly, the electrically conductive surfaces 161, 162, and 163 may be implemented. The electrically conductive surface (sensing surface) 161 contacts the bottom surface 122 of the touch key 120.

The second member 150 may have the length L2, the width W, and the thickness T2. The length L2 of the second member 150 may be less than the length L of the first member 140. The second member 150 may include a second gasket 151 that is electrically insulating, and a second sheet 182 that is electrically conductive and surrounds surfaces 152, 153, and 154 of the second gasket 151 in the longitudinal direction Y and the thickness direction Z. The second gasket 151 may be formed of an electrically insulating material having elasticity. For example, the second gasket 151 may be formed of polyurethane sponge. The second sheet 182 covers the surfaces 152, 153, and 154 of the second gasket 151 in the thickness direction Z and the longitudinal direction Y. The second sheet 182 may surround the surfaces 152, 153, and 154 of the second gasket 151 in the thickness direction Z and the longitudinal direction Y. The second sheet 182 may be adhered to the surfaces 152, 153, and 154 of the second gasket 151 in the thickness direction Z and the longitudinal direction Y. The second sheet 182 may include an electrically conductive fabric. The second sheet 182 may be, for example, a polyester fabric including nickel (Ni) or copper (Cu). Accordingly, the electrically conductive surfaces 164 and 165 may be implemented. The electrically conductive surface (connection surface) 165 contacts the conductive land 131.

The second member 150 is adhered to the first member 140 in the thickness direction Z. The second member 150 may be adhered to the surface 163 by using an electrically conductive double-sided tape (or adhesive) 183. Accordingly, the surface (sensing surface) 161 and the surface (connection surface) 165 may be electrically connected to each other by the surfaces 162, 163, and 164.

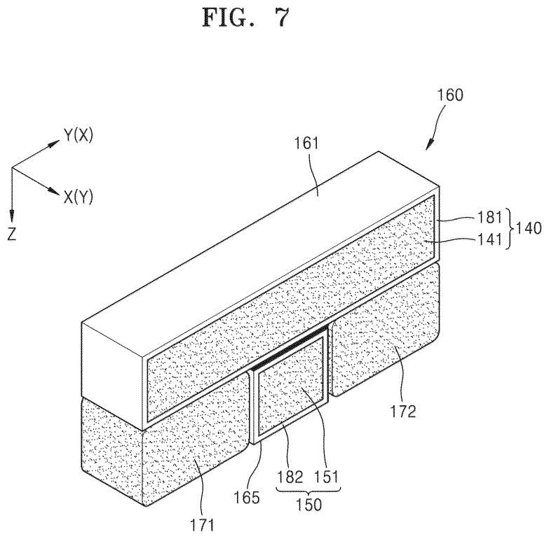

FIG. 7 is a schematic perspective view illustrating an example of the connection member 160. An example of the connection member 160 of FIG. 7 is different from an example of the connection member 160 of FIG. 6 in that the support members 171 and 172 are included. The difference will be mainly described. Referring to FIG. 7, the support members 171 and 172 are located on both sides of the second member 150 in the longitudinal direction Y. The support members 171 and 172 may be adhered to the surface 163 of the first member 140 in the thickness direction Z. Each of the support members 171 and 172 may be formed of an electrically insulating material having elasticity. The support members 171 and 172 may be formed of, for example, polyurethane sponge. The support members 171 and 172 may be adhered to the surface 163 of the first member 140 by using a double-sided tape or an adhesive. The double-sided tape or the adhesive may be electrically insulating. According to this configuration, the surface (sensing surface) 161 of the first member 140 may stably contact the bottom surface 122 of the touch key 120.

Although embodiments of the connection member 160 having a substantially T-shape and including electrically insulating surfaces in the width direction W have been described, the connection member 160 may have various shapes.

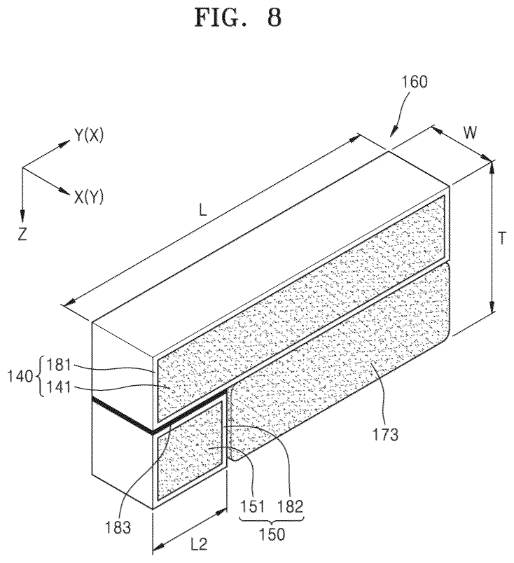

FIG. 8 is a schematic perspective view illustrating an example of the connection member 160. An example of the connection member 160 of FIG. 8 is different from an example of the connection member 160 of FIG. 7 in that the connection member 160 of FIG. 8 has a substantially inverted “L”-shape. The difference will be mainly described. The connection member 160 may include the first member 140, and the second member 150 adhered to a bottom surface of the first member 140 by using the double-sided tape (or adhesive) 183 that is electrically conductive. The length L2 of the second member 150 is less than the length L of the first member 140. The second member 150 is located near an end of the first member 140 in the longitudinal direction Y and is adhered to the bottom surface of the first member 140. Accordingly, the connection member 160 having a substantially inverted “L”-shape may be implemented. The connection member 160 may further include a support member 173. The support member 173 is located between the sensor substrate 130 and the first member 140 to support the first member 140. The support member 173 may be formed of an electrically insulating material, for example, polyurethane sponge. The support member 173 may be adhered to the bottom surface of the first member 140 by using a double-sided tape or an adhesive. The double-sided tape or the adhesive may be electrically insulating.

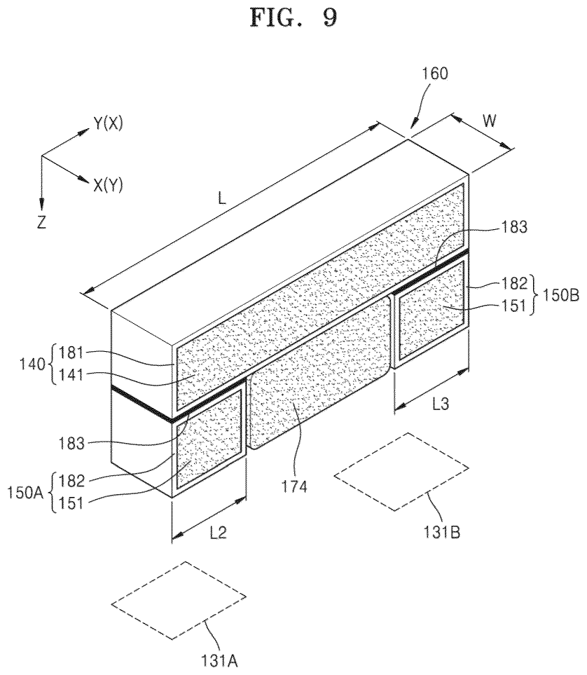

FIG. 9 is a schematic perspective view illustrating an example of the connection member 160. An example of the connection member 160 of FIG. 9 is different from an example of the connection member 160 of FIG. 7 in that the connection member 160 of FIG. 9 includes two second members 150A and 150B. The difference will be mainly described. The connection member 160 may include the first member 140, and one pair of second members 150A and 150B adhered to a bottom surface of the first member 140 by using the double-sided tape (or adhesive) 183. Lengths L2 and L3 of the pair of second members 150A and 150B are each less than the length L of the first member 140. The pair of second members 150A and 150B are spaced apart from each other in the longitudinal direction Y and are adhered to the bottom surface of the first member 140. For example, the second member 150A is located near one end of the first member 140 in the longitudinal direction Y and is adhered to the bottom surface of the first member 140. The second member 150B is located near the other end of the first member 140 in the longitudinal direction Y and is adhered to the bottom surface of the first member 140. One pair of conductive lands 131A and 131B respectively contacting the pair of second members 150A and 150B may be provided on the sensor substrate 130. The pair of conductive lands 131A and 131B are provided on the printed circuit sensor substrate 130 to be spaced apart from each other in the longitudinal direction Y to correspond to the pair of second members 150A and 150B. The connection member 160 may further include a support member 174. The support member 174 is located between the sensor substrate 130 and the first member 140 to support the first member 140. The support member 174 is located between the pair of second members 150A and 150B in the longitudinal direction Y. The support member 174 may be formed of an electrically insulating material, for example, polyurethane sponge. The support member 174 may be adhered to the bottom surface of the first member 140 by using a double-sided tape or an adhesive. The double-sided tape or the adhesive may be electrically insulating.

Although a structure in which two electronic devices 1 are located parallel to each other in a horizontal direction has been described in the above embodiments, the two electronic devices may be arranged parallel to each other in a longitudinal direction. A door may be opened/closed in the longitudinal direction. The door sensor 100 to which the above examples of the connection member 160 are applied may also be applied to an electronic device including a door that is opened/closed in the longitudinal direction. This type of electronic device may be, for example, an oven.

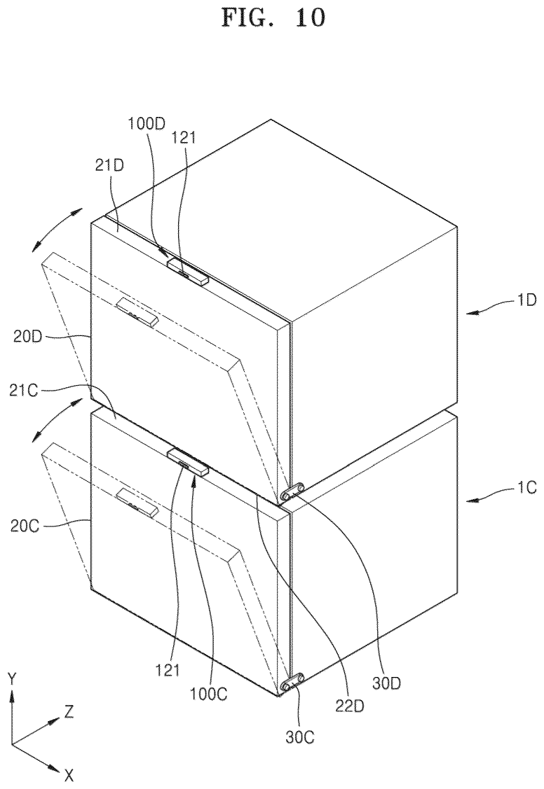

FIG. 10 is a schematic perspective view illustrating an example of an arrangement of two electronic devices 1C and 1D. Referring to FIG. 10, the two electronic devices 1C and 1D are arranged parallel to each other in a longitudinal direction. The electronic devices 1C and 1D respectively include doors 20C and 20D that are opened/closed in the longitudinal direction around hinges 30C and 30D. The door sensors 1000 and 100D are located adjacent to open-side edges 21C and 21D of the doors 20C and 20D. Structures of the door sensors 1000 and 100D may be the same as those in FIGS. 2, 3, and 6 to 9. Because the length L of the connection member 160 is a value measured in a direction parallel to the open-side edges 21C and 21D of the doors 20C and 20D, and thus, is a value measured in the X direction. The width W of the connection member 160 is a value measured in an opening/closing direction of the doors 20C and 20D, and thus, is a value measured in the Y direction. Accordingly, referring to FIGS. 2, 3, and 6 to 9, directions in parentheses are applied for the X direction and the Y direction.

The two electronic devices 1C and 1D are arranged so that a hinge-side edge 22D of the door 20D of the electronic device 1D is adjacent to the open-side edge 21C of the door 20C of the electronic device 1C. Each of the doors 20C and 20D entirely or partially includes a conductor, for example, a metal. When the door 20D of the electronic device 1D is opened/closed in a state where the door 20C of the electronic device 1C is closed, as described above with reference to FIG. 5, parasitic capacitance due to the conductor of the door 20D of the electronic device 1D may affect the door sensor 100C of the electronic device 1C. By employing the door sensor 100 to which the connection member 160 of FIGS. 2, 3, and 6 to 9 is applied as the door sensors 100C and 100D, the risk of door malfunction due to parasitic capacitance may be reduced. Also, a capacitive door sensor with improved operational stability and an electronic device employing the same may be implemented.

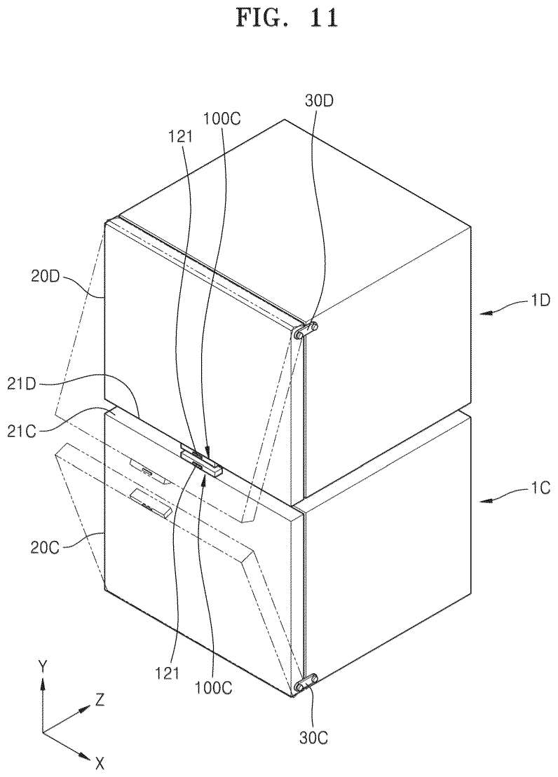

FIG. 11 is a schematic perspective view illustrating an example of an arrangement of two electronic devices 1C and 1D. Referring to FIG. 11, the two electronic devices 1C and 1D are arranged parallel to each other in a longitudinal direction. The electronic devices 1C and 1D respectively include the doors 20C and 20D that rotate around the hinges 30C and 30D to be opened/closed in the longitudinal direction. The doors 20C and 20D rotate in opposite directions. The door sensors 100C and 100D are arranged so that the open-side edges 21C and 21D of the doors 20C and 20D are adjacent to each other. Structures of the door sensors 100C and 100D may be the same as those described with reference to FIGS. 2, 3, and 6 to 9. The length L of the connection member 160 is a value measured in a direction parallel to the open-side edges 21C and 21D of the doors 20C and 20D, and thus, is a value measured in the X direction. The width W of the connection member 160 is a value measured in an opening/closing direction of the doors 20C and 20D, and thus, is a value measured in the Y direction. Accordingly, referring to FIGS. 2, 3, and 6 to 9, directions in parentheses are applied for the X direction and the Y direction.

The two electronic devices 1C and 1D are arranged so that the open-side edges 21C and 21D of the doors 20C and 20D are adjacent to each other. Each of the doors 20C and 20D entirely or partially includes a conductor, for example, a metal. When the door 20D of the electronic device 1D is opened/closed in a state where the door 20C of the electronic device 1C is closed, as described with reference to FIG. 4, parasitic capacitance due to the conductor of the door 20D of the electronic device 1D may affect the door sensor 1000 of the electronic device 1C. On the contrary, when the door 20C of the electronic device 1C is opened/closed in a state where the door 20D of the electronic device 1D is closed, parasitic capacitance due to the conductor of the door 20C of the electronic device 1C may affect the door sensor 100D of the electronic device 1D. By employing the door sensor 100 to which the connection member 160 of FIGS. 2, 3, and 6 to 9 is applied as the door sensors 1000 and 100D, the risk of door malfunction due to parasitic capacitance may be reduced. Also, a capacitive door sensor with improved operational stability and an electronic device employing the same may be implemented.

An electronic device according to an aspect of the disclosure includes a main body, a door configured to open/close at least a part of the main body, and a door sensor provided adjacent to an open-side edge of the door and configured to detect a touch input by using a capacitive method. The door sensor includes a touch key configured to receive a touch input, a connection member including a sensing surface contacting the touch key, and a connection surface, and a sensor substrate including a conductive land contacting the connection surface, surfaces of the connection member in a thickness direction including the sensing surface and the connection surface and surfaces of the connection member in a longitudinal direction parallel to the open-side edge of the door are electrically conductive surfaces, and surfaces of the connection member in a width direction, which is an opening/closing direction of the door, are electrically non-conductive surfaces.

According to an embodiment, the connection member may include a first portion including the sensing surface and a second portion extending from the first portion in the thickness direction and including the connection surface, wherein a length of the second portion is less than a length of the first portion.

The electronic device according to an embodiment may further include support members that are electrically insulating, are located between the sensor substrate and the first portion, and support the first portion. The support members may be adhered to the first portion.

According to an embodiment, a length of the conductive land may be less than a length of the first portion.

According to an embodiment, the connection member may have elasticity.

According to an embodiment, the connection member may include a first member including a first gasket that is electrically insulating, and a first sheet that is electrically conductive and covers surfaces of the first gasket in the longitudinal direction and the thickness direction, and a second member including a second gasket that is electrically insulating, and a second sheet that is electrically conductive and covers surfaces of the second gasket in the longitudinal direction and the thickness direction, wherein the first member and the second member are adhered to each other by an electrically conductive tape in the thickness direction.

According to an embodiment, a length of the second member may be less than a length of the first member.

According to an embodiment, the electronic device may further include support members that are electrically insulating, are located between the sensor substrate and the first member, and support the first member.

According to an embodiment, each of the first gasket and the second gasket may be formed of an elastic material.

A capacitive door sensor according to an embodiment of the disclosure includes a touch key configured to receive a touch input, a connection member having elasticity and including a sensing surface contacting the touch key and a connection surface, and a sensor substrate including a conductive land contacting the connection surface, wherein surfaces of the connection member in a thickness direction including the sensing surface and the connection surface and surfaces of the connection member in a longitudinal direction are electrically conductive surfaces, and surfaces of the connection member in a width direction are electrically non-conductive surfaces.

According to an embodiment, the connection member may include a first portion including the sensing surface, and a second portion extending from the first portion in the thickness direction and including the connection surface, wherein a length of the second portion is less than a length of the first portion.

The capacitive door sensor according to an embodiment may further include a support member that is electrically insulating, is located between the sensor substrate and the first portion, and supports the first portion. According to an embodiment, the support member may be adhered to the first portion.

According to an embodiment, a length of the conductive land may be less than a length of the first portion.

According to an embodiment, the connection member may have elasticity.

According to an embodiment, the connection member may include a first member including a first gasket that is electrically insulating and has elasticity, and a first sheet that is electrically conductive and covers surfaces of the first gasket in the longitudinal direction and the thickness direction, and a second member including a second gasket that is electrically insulating and has elasticity, and a second sheet that is electrically conductive and covers surfaces of the second gasket in the longitudinal direction and the thickness direction, wherein the first member and the second member are adhered to each other by an electrically conductive tape in the thickness direction.

According to an embodiment, a length of the second member may be less than a length of the first member.

According to an embodiment, the capacitive door sensor may further include support members that are electrically insulating, are located between the sensor substrate and the first member, and support the first member.

According to an embodiment, each of the first gasket and the second gasket may be formed of an elastic material.

According to a capacitive door sensor and an electronic device employing the same according to the disclosure, a capacitive door sensor capable of reducing the influence of a surrounding conductor and an electronic device employing the capacitive door sensor may be implemented. Also, a capacitive door sensor with improved operational stability and an electronic device employing the same may be implemented.

Although embodiments have been described in detail above, the scope of the disclosure is not limited thereto, and various modifications and improvements made by one of ordinary skill in the art by using the basic concept of the disclosure defined by the claims are also within the scope of the disclosure.

1. An electronic device comprising:
a main body having an opening;
a door configured to open and close at least a part of the opening of the main body; and
a door sensor, provided relative to an open-side edge of the door, and configured to detect a touch input by using a capacitive method,
wherein the door sensor comprises:
a touch key configured to receive the touch input;
a sensor substrate comprising a conductive land;
a connection member comprising a sensing surface contacting the touch key, and a connection surface contacting the conductive land so that the touch key is electrically connected to the conductive land through the connection member; and
wherein surfaces of the connection member along a thickness direction comprises the sensing surface and the connection surface and surfaces of the connection along a longitudinal direction parallel to the open-side edge of the door are electrically conductive surfaces, and
surfaces of the connection member along a width direction, which is an opening/closing direction of the door, are electrically non-conductive surfaces.

2. The electronic device of claim 1, wherein the door sensor is adjacent to the open-side edge of the door,
the connection member comprises a first portion comprising the sensing surface and a second portion extending from the first portion along the thickness direction comprising the connection surface,
wherein a length of the second portion is less than a length of the first portion.

3. The electronic device of claim 2, further comprising:
at least one support member, which is electrically insulating, located between the sensor substrate and the first portion, to support the first portion.

4. The electronic device of claim 3, wherein the at least one support member is adhered to the first portion.

5. The electronic device of claim 2, wherein a length of the conductive land is less than the length of the first portion.

6. The electronic device of claim 1, wherein the connection member has elasticity.

7. The electronic device of claim 1, wherein the connection member comprises:
a first member comprising a first gasket that is electrically insulating and has elasticity, and a first sheet that is electrically conductive and surrounds surfaces of the first gasket along the longitudinal direction and the thickness direction; and
a second member comprising a second gasket that is electrically insulating and has elasticity, and a second sheet that is electrically conductive and surrounds surfaces of the second gasket along the longitudinal direction and the thickness direction,
wherein the first member and the second member are adhered to each other by an electrically conductive tape along the thickness direction.

8. The electronic device of claim 7, wherein a length of the second member is less than a length of the first member.

9. The electronic device of claim 7, further comprising:
at least one support member, which is electrically insulating, located between the sensor substrate and the first member, to support the first member.

10. The electronic device of claim 7, wherein each of the first gasket and the second gasket is formed of an elastic material.

11. A capacitive door sensor comprising:
a touch key configured to receive a touch input;
a sensor substrate comprising a conductive land;
a connection member comprising a sensing surface contacting the touch key and a connection surface contacting the conductive land so that the touch key is electrically connected to the conductive land through the connection member; and
wherein surfaces of the connection member along a thickness direction comprise the sensing surface and the connection surface and surfaces of the connection member along a longitudinal direction are electrically conductive surfaces, and
surfaces of the connection member along a width direction are electrically non-conductive surfaces.

12. The capacitive door sensor of claim 11, wherein the connection member comprises a first portion comprising the sensing surface, and a second portion extending from the first portion along the thickness direction and comprising the connection surface,
wherein a length of the second portion is less than a length of the first portion.

13. The capacitive door sensor of claim 12, further comprising:
at least one support member, which is electrically insulating, located between the sensor substrate and the first portion, to support the first portion.

14. The capacitive door sensor of claim 13, wherein the support members are adhered to the first portion.

15. The capacitive door sensor of claim 12, wherein a length of the conductive land is less than the length of the first portion.

16. The capacitive door sensor of claim 11, wherein the connection member has elasticity.

17. The capacitive door sensor of claim 11, wherein the connection member comprises:
a first member comprising a first gasket that is electrically insulating and has elasticity, and a first sheet that is electrically conductive and surrounds surfaces of the first gasket along the longitudinal direction and the thickness direction; and
a second member comprising a second gasket that is electrically insulating and has elasticity, and a second sheet that is electrically conductive and surrounds surfaces of the second gasket along the longitudinal direction and the thickness direction,
wherein the first member and the second member are adhered to each other by an electrically conductive tape along the thickness direction.

18. The capacitive door sensor of claim 17, further comprising at least one support member, which is electrically insulating, located between the sensor substrate and the first member, to support the first member.

19. The capacitive door sensor of claim 17, wherein a length of the second member is less than a length of the first member.

20. The capacitive door sensor of claim 17, wherein each of the first gasket and the second gasket is formed of an elastic material.
